(19) United States
(12) Patent Application Publication
(10) Pub. No.: US 2012/0138968 A1
(43) Pub. Date: Jun. 7, 2012

(54) SEMICONDUCTOR PACKAGE AND DISPLAY PANEL ASSEMBLY HAVING THE SAME

(76) Inventors: Na-Rae Shin, Yongin-si (KR); So-Young Lim, Hwaseong-si (KR); Chul-Woo Kim, Namdong-gu (KR); Ye-Chung Chung, Hwaseong-si (KR)

(21) Appl. No.: 13/240,759

(22) Filed: Sep. 22, 2011

(30) Foreign Application Priority Data
Dec. 7, 2010 (KR) 10-2010-0124279

(51) Int. Cl. H01L 23/02; H01L 33/48

(52) U.S. Cl. 257/88; 257/690; 257/E23.18; 257/E33.058

(57) ABSTRACT

Provided are a semiconductor package with a reduced lead pitch, and a display panel assembly having the semiconductor package. The semiconductor package includes a film having a hole formed therein, a plating pattern formed under the film and forming a wire; a semiconductor chip placed in the hole and electrically connected to the plating pattern; and a first passivation layer formed at a side opposite to the semiconductor chip about the plating pattern and protecting the plating pattern.

### CROSS-REFERENCE TO RELATED APPLICATION

This application claims priority from Korean Patent Application No. 10-2010-0124279 filed on Dec. 7, 2010 in the Korean Intellectual Property Office, and all the benefits accruing therefrom under 35 U.S.C. 119, the contents of which are herein incorporated by reference in its entirety.

### BACKGROUND

1. Technical Field

The embodiments of the present inventive concept relate to a semiconductor package and a display panel assembly having the semiconductor package, and more particularly to a semiconductor package with a reduced pitch between leads, and a display panel assembly having the semiconductor package.

2. Discussion of the Related Art

Some semiconductor packages used in semiconductor mounting include leads connected to signal lines of a display panel. As high-resolution display panels are developed, a pitch between signal lines of the display panels has been reduced. Accordingly, there is a need for a semiconductor package with a reduced pitch between leads to correspond to the reduced pitch between signal lines of the display panel.

### SUMMARY

Exemplary embodiments of the present inventive concept provide a semiconductor package with a reduced pitch between leads (hereinafter, also referred to as “lead pitch”), and a display panel assembly having the semiconductor package.

According to an embodiment of the present inventive concept, there is provided a semiconductor package including a film having a hole formed therein, a plating pattern formed under the film and forming a wire, a semiconductor chip placed in the hole and electrically connected to the plating pattern, and a first passivation layer formed on the semiconductor chip and the plating pattern.

According to an embodiment of the present inventive concept, there is provided a display panel assembly comprising a display panel having a plurality of connection terminals along its periphery, receiving driving signals from the outside through the connection terminals to display picture information, and a semiconductor package having semiconductor chips for driving the display panel mounted thereon and electrically connected to the connection terminals, wherein the semiconductor package comprises: a film having a hole formed therein, a plating pattern formed under the film and forming a wire, a semiconductor chip placed in the hole and electrically connected to the plating pattern, and a first passivation layer formed on the semiconductor chip and the plating pattern.

According to an embodiment of the present invention, there is provided a semiconductor package comprising a plating layer, a semiconductor chip on the plating layer, wherein the semiconductor chip is electrically connected to the plating layer via a metal pad, and a film on the plating layer, wherein the film surrounds the semiconductor chip.

### BRIEF DESCRIPTION OF THE DRAWINGS

The embodiments of the present inventive concept will become more apparent by describing in detail exemplary embodiments thereof with reference to the attached drawings in which:

FIG. 1 is a plan view illustrating a semiconductor package according to an embodiment of the present inventive concept;

FIG. 2 is a cross-sectional view taken along line A-A′ of FIG. 1;

FIG. 3 is a plan view illustrating a semiconductor package according to an embodiment of the present inventive concept;

FIG. 4 is a cross-sectional view illustrating a semiconductor package according to an embodiment of the present inventive concept, as taken along line B-B′ of FIG. 3;

FIG. 5 is a cross-sectional view illustrating a semiconductor package according to an embodiment of the present inventive concept, as taken along line B-B′ of FIG. 3;

FIG. 6 is a cross-sectional view illustrating a semiconductor package according to an embodiment of the present inventive concept, as taken along line B-B′ of FIG. 3;

FIG. 7 is a plan view illustrating a redistribution chip in a semiconductor package according to an embodiment of the present inventive concept;

FIG. 8 is a cross-sectional view taken along line C-C′ of FIG. 7; and

FIG. 9 is a perspective view of a display panel assembly according to an embodiment of the present inventive concept.

### DETAILED DESCRIPTION OF THE EMBODIMENTS

The embodiments of the present inventive concept will now be described more fully hereinafter with reference to the accompanying drawings, in which exemplary embodiments of the inventive concept are shown. This inventive concept may, however, be embodied in different forms and should not be construed as limited to the embodiments set forth herein. The same reference numbers may indicate the same components throughout the specification. In the attached figures, the thickness of layers and regions may be exaggerated for clarity.

It will also be understood that when a layer is referred to as being “on” another layer or substrate, it can be directly on the other layer or substrate, or intervening layers may also be present.

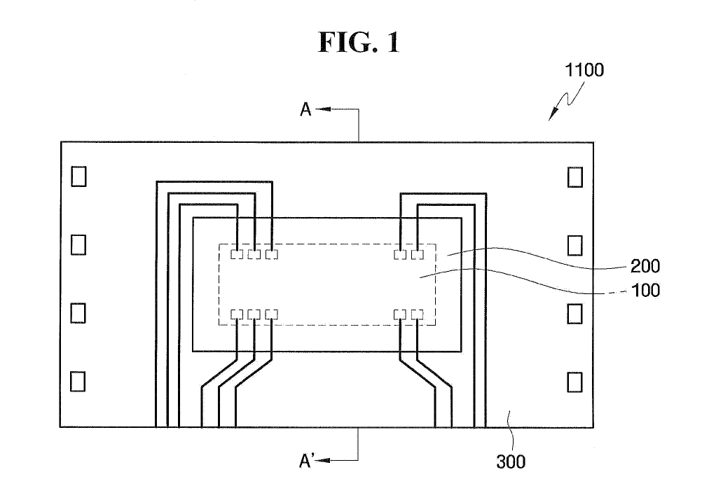

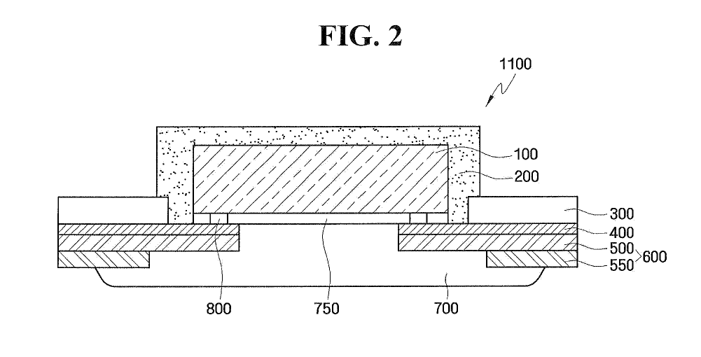

Hereinafter, a semiconductor package according to an embodiment of the present inventive concept will be described with reference to FIGS. 1 and 2. FIG. 1 is a plan view illustrating a semiconductor package according to an embodiment of the present inventive concept, and FIG. 2 is a cross-sectional view taken along line A-A′ of FIG. 1.

Referring to FIGS. 1 and 2, the semiconductor package 1100 according to the embodiment of the present inventive concept includes a semiconductor chip 100, a metal pad 800, a molding member 200, a film 300, a seed layer 400, a plating pattern 600 including a first plating pattern 500 and a second plating pattern 550, and a first passivation layer 700.

The semiconductor package 1100 is subjected to sequential plating steps to reduce a lead pitch, which is described below.

The semiconductor chip 100 is an integrated circuit made of a semiconductor having an electric conductivity that is higher than a nonconductor and lower than a conductor, such as a metal. The semiconductor chip 100 is formed of various elements, such as transistors, resistors, or condensers, integrated on a silicon wafer.

The semiconductor chip 100 is placed in a hole formed in the film 300, and the metal pad 800 is positioned under the semiconductor chip 100, so that the semiconductor chip 100 is electrically connected to the plating pattern 600 through the metal pad 800. A second passivation layer 750 is formed in a space under the semiconductor chip 100, thereby protecting the semiconductor chip 100. The molding member 200 covers the semiconductor chip 100 and a portion of the film 300, thereby insulating the semiconductor chip 100 from an outside and integrally forming the semiconductor chip 100 with the film 300.

The metal pad 800 is made of a conductive material and electrically connects the semiconductor chip 100 to a substrate. The metal pad 800 is formed under the semiconductor chip 100 and electrically connects the semiconductor chip 100 to the plating pattern 600.

The molding member 200 fills the hole of the film 300 while covering the semiconductor chip 100, the metal pad 800, and the second passivation layer 750. The molding member 200 covers a portion of the film 300 such that two opposite ends of the film 300 penetrate into the molding member 200. An exemplary material of the molding member 200 includes an epoxy molding compound (EMC). According to embodiments, resin, monomer for the film 300 made of polyimide (PI), or photo solder resist (PSR) for a ball grid array (BGA), is also used as the material of the molding member 200. The molding member 200 fixes the semiconductor chip 100 and the film 300 to a carrier plate used at an initial stage of a semiconductor package manufacturing process and allows the semiconductor chip 100 and the film 300 to be integrally formed.

The film 300 is made of an insulating material, for example, polyimide resin or polyester resin. A hole is formed in the film 300 to provide for a space in which the semiconductor chip 100 can be placed. The film 300 provides a space for the plating pattern 600. The seed layer 400 is sputtered on a bottom surface of the film 300 and is plated with a metal, such as copper, to form the plating pattern 600.

In the process of forming the plating pattern 600, the first plating pattern 500 is first formed by sputtering the seed layer 400 on a surface opposite to a surface where the semiconductor chip 100 is placed, that is, on a bottom surface of the film 300, and coating a photoresist on the seed layer 400. The photoresist may be a photosensitive material. Thereafter, a process of forming a mask pattern is conducted, which is referred to as photolithography. In the photolithography process, an exposure step of selectively radiating light using a mask is performed and the photoresist is etched, thereby forming the mask pattern.

Thereafter, a plating layer, such as a first plating pattern 500, is formed in the space from which the photoresist is removed by etching. The plating layer is formed of, for example, copper by electroplating or electroless plating. The plating pattern 600 is subjected to gradual plating. The first plating pattern 500 is formed to be thinner than a general plating layer to reduce a lead pitch. A thin plating layer is more adoptable than a thick plating layer for implementing a reduced lead pitch. The first plating pattern 500 has a thickness in a range of about 3 to about 8 μm, but is not limited thereto.

As shown in FIG. 2, a distance between two opposite ends of the first plating pattern 500 is smaller than a distance between two opposite ends of the second plating pattern 550 with respect to the semiconductor chip.

A thin plating layer is more adoptable than a thick plating layer for implementing a reduced lead pitch. By making the first plating pattern 500 thinner than a general plating layer, a pitch between leads can be reduced. As a result, the same number of pads can be disposed in a smaller semiconductor chip 100, and more pads can be disposed in the same semiconductor chip 100, thereby achieving lower weight, thinness, and compactness of a semiconductor mounted product.

The second plating pattern 550 is formed under the first plating pattern 500. When implementing a reduced lead pitch by forming a thin first plating pattern 500, the second plating pattern 550 is further formed to allow the overall plating layer to have a predetermined thickness to maintain electrical performance. The second plating pattern 550 has a thickness in a range of about 5 to about 30 μm, but is not limited thereto.

As shown in FIG. 2, the second plating pattern 550 is configured to be less extended toward the semiconductor chip 100 than the first plating pattern 500. After the plating pattern 600 including the first plating pattern 500 and the second plating pattern 550 is formed, portions of the first plating pattern 500 and the seed layer 400 positioned between the two opposite metal pads 800 are removed. The portions of the first plating pattern 500 and the seed layer are removed to allow current to flow through the semiconductor chip 100. Without removing the portions of the first plating pattern 500 and the seed layer 400 positioned between the two opposite metal pads 800, the current may not pass through the semiconductor chip 100.

The first passivation layer 700, also called a solder resist, may be formed to be opposite to the semiconductor chip 100 with respect to the film 300 and to cover the plating pattern 600. The first passivation layer 700, which includes an insulating permanent coating material, is a coating layer that covers interconnect circuits to prevent unintended welding from occurring when mounting components. The first passivation layer 700 covers portions other than a component mounted portion.

The first passivation layer 700 prevents short circuit, corrosion, contamination, etc. of an electronic circuit board, and remains on the board as a coating layer even after the board is formed, thereby protecting the circuit against external impacts, moisture or chemicals.

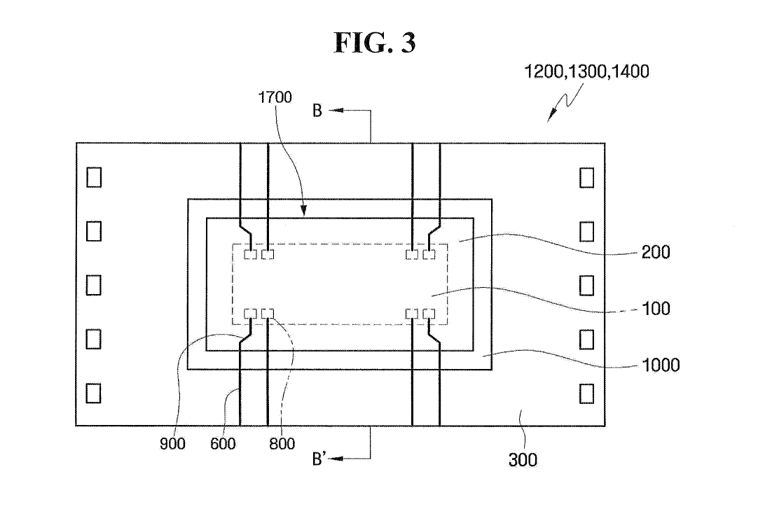

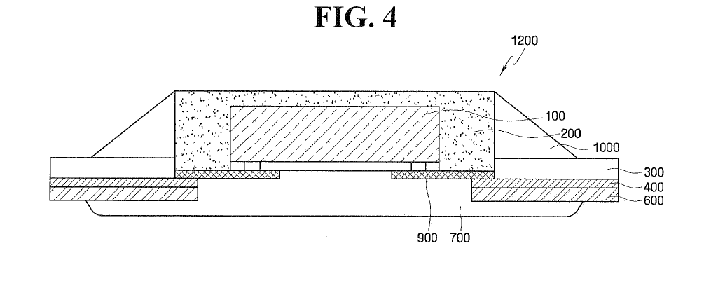

FIG. 3 is a plan view illustrating a semiconductor package according to an embodiment of the present inventive concept, and FIG. 4 is a cross-sectional view illustrating a semiconductor package according to an embodiment of the present inventive concept, as taken along line B-B′ of FIG. 3.

Referring to FIGS. 3 and 4, a semiconductor package 1200 according to an embodiment of the present inventive concept includes a redistribution chip 1700. The redistribution chip 1700 is electrically connected to a plating pattern formed under a film 300, thereby forming the semiconductor package 1200.

The redistribution chip 1700 includes a semiconductor chip 100, a molding member 200, a metal pad 800, a second passivation layer 750, and a redistribution pattern layer 900.

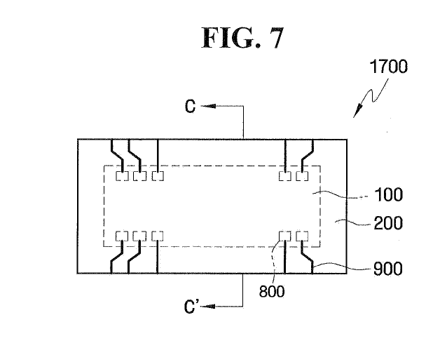

The redistribution chip 1700 implements a small lead pitch on a surface of the molding member 200 using an FAB process including molding the semiconductor chip 100 with the molding member 200 to form a pattern. The redistribution pattern layer 900 formed on a bottom surface of the molding member 200 and the plating pattern 600 formed under the film 300 are electrically connected to each other, thereby completing the semiconductor package 1200. And, as shown in FIG. 3 and FIG. 7, a pattern pitch in the redistribution pattern layer 900 can be increased by the FAB process. For example, a first pattern pitch in a first side of the redistribution pattern layer 900 is different from a second pattern pitch in a second side of the redistribution pattern layer 900. The first side of the redistribution pattern layer 900 is adjacent to the metal pads 800, and the second side of the redistribution pattern layer 900 is adjacent to the plating pattern 600. Namely, the first pattern pitch is fine to correspond to small pad pitch of the metal pads 800. However, the second pattern pitch is bigger than the first pattern pitch. And, the plating pattern 600 can be electrically connected to the second side of the redistribution pattern layer 900 which has the second pattern pitch. A pitch of the plating pattern 600 may be bigger than a pitch of the metal pads 800. Therefore, by using the redistribution pattern layer 900, it is possible to correspond to the small pad pitch of the metal pads 800 without reducing the pitch of the plating pattern 600 under the film 300. Since bonding is performed using an adhesive rather than by thermal compression, the film 300 is not deformed, thereby preventing various layers of the semiconductor package from being misaligned.

Referring to FIG. 4, the molding member 200 fills a hole formed in the film 300, and a coating material 1000 is formed on a top surface of the film 300. The coating material 1000 and a side surface of the molding member 200 contact each other. A portion of the film 300 does not penetrate into the molding member 200.

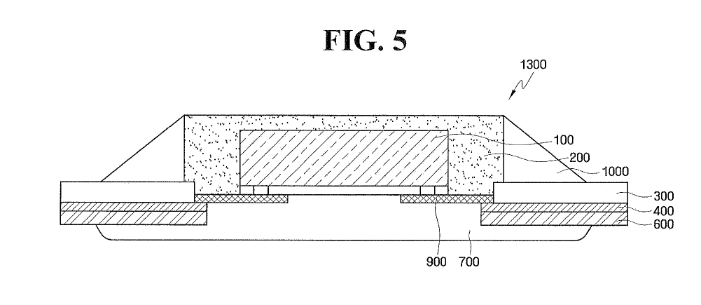

FIG. 5 is a cross-sectional view illustrating a semiconductor package according to an embodiment of the present inventive concept, as taken along line B-B′ of FIG. 3.

Referring to FIGS. 3 and 5, a semiconductor package 1300 according to an embodiment of the present inventive concept includes a redistribution chip 1700. The redistribution chip 1700 is electrically connected to a plating pattern formed under a film 300, thereby forming the semiconductor package 1300.

Referring to FIG. 5, a molding member 200 covers a portion of the film 300 and fills a hole formed in the film 300 to prevent a coating material 1000 coated on a top surface of the film 300 from flowing out between the film 300 and the molding member 200, which is different from the semiconductor package 1200 shown in FIG. 4.

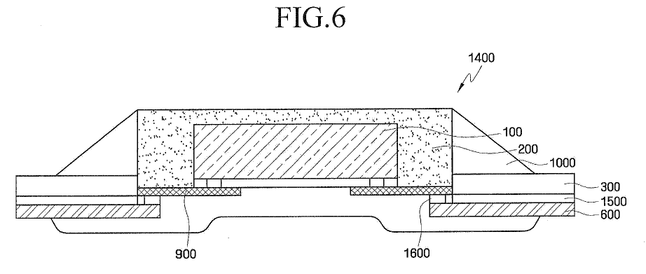

FIG. 6 is a cross-sectional view illustrating a semiconductor package according to an embodiment of the present inventive concept, as taken along line B-B′ of FIG. 3.

Referring to FIGS. 3 and 6, a semiconductor package 1400 according to an embodiment of the present inventive concept includes a redistribution chip 1700. The semiconductor package 1400 shown in FIG. 6 has a structure in which the redistribution chip 1700 is attached to a tape carrier package (TCP), which is a semiconductor package. The semiconductor package 1400 can be fabricated using the redistribution chip 1700 without changing the conventional fabricating/assembling process of the film 300.

A redistribution pattern layer 900 formed on a bottom surface of a molding member 200 through a semiconductor device fabrication (FAB) process is electrically connected to a plating layer 600 formed under a film 300 through a connection member 1600. The connection member 1600 is a connection bump, such as a solder ball, or an anisotropic conductive film (ACF). The connection bump is formed on the redistribution pattern layer 900 and is then connected to the plating pattern 600.

In the case that the connection member 1600 is an ACF, the connection member 1600 includes conductive balls. Anisotropy refers to a property of being electrically conductive at one side but being insulated at the other side. The ACF refers to a film-type adhesive having conductive particles dispersed in a curable adhesive component. When the ACF is compressed between electrodes, the conductive particles prevent current from flowing in a direction parallel to the ACF while allowing the current to flow in a direction perpendicular to the ACF. As such, the conductive particles of the ACF establish an electrical connection between two circuits.

In the semiconductor package 1400 shown in FIG. 6, an adhesive material 1500 is positioned between the film 300 and the plating pattern 600. The adhesive material 1500 includes an epoxy-based resin. According to an embodiment, the adhesive material 1500 further includes SiO₂ added to the epoxy-based resin. However, the connection member between the film 300 and the plating pattern 600 is not limited to the adhesive material 1500, but the film 300 and the plating pattern 600 may be connected to each other by other methods.

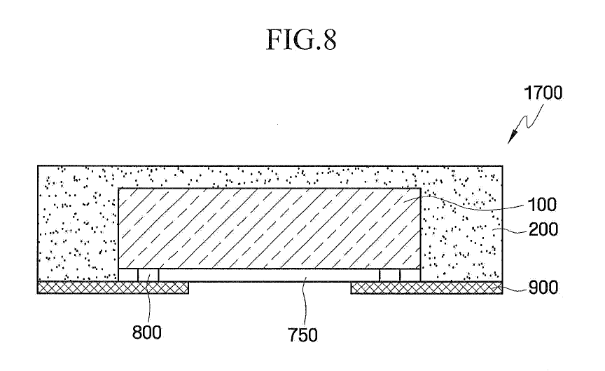

FIG. 7 is a plan view illustrating the redistribution chip 1700 in the semiconductor package 1200, 1300, and 1400 according to embodiment of the present inventive concept, and FIG. 8 is a cross-sectional view taken along line C-C′ of FIG. 7.

Referring to FIGS. 7 and 8, a redistribution chip 1700 according to an embodiment of the present inventive concept includes a semiconductor chip 100, a molding member 200, a second passivation layer 750, and a redistribution pattern 900.

The redistribution pattern 900 is formed on a bottom surface of the molding member 200 covering the semiconductor chip 100 through a FAB process. The redistribution pattern 900 is electrically connected to a plating pattern 600 formed under a film 300 directly or through a connection member. Since a pattern pitch of the redistribution pattern 900 can be increased through the FAB process, it is possible to correspond to the small pad pitch of the metal pads 800 without reducing a pitch of the plating pattern 600.

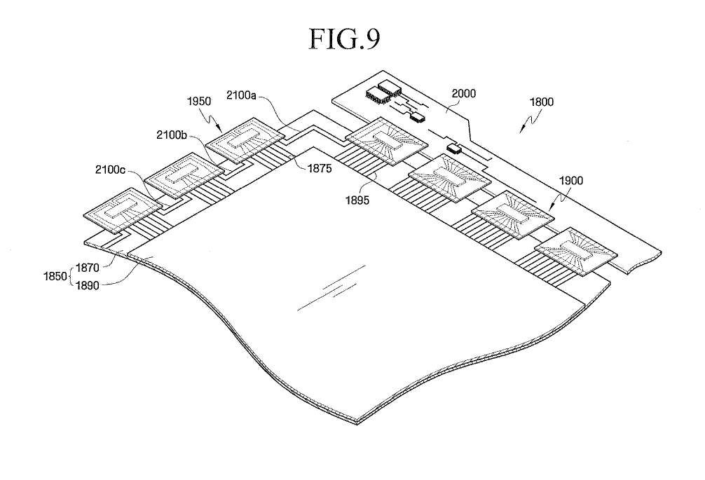

FIG. 9 is a perspective view of a display panel assembly according to an embodiment of the present inventive concept. The semiconductor packages described in connection with FIGS. 1 to 8 constitute gate chip film packages and data chip film packages, which are components of a display panel assembly.

Referring to FIG. 9, a display panel assembly 1800 includes a display panel 1850, gate chip film packages 1950, data chip film packages 1900, and a printed circuit board 2000.

The display panel 1850 includes a lower substrate 1870 and an upper substrate 1890 that is smaller than the lower substrate 1870 and is disposed on the lower substrate 1870. The lower substrate 1870 includes gate lines 1875, data lines 1895, thin film transistors, pixel electrodes, etc. The upper substrate 1890 includes black matrixes, color filters, a common electrode, etc. A liquid crystal layer (not shown) is disposed between the lower substrate 1870 and the upper substrate 1890.

The gate chip film packages 1950 are connected to the gate lines 1875 formed on the lower substrate 1870, and the data chip film packages 1900 are connected to the data lines 1895 formed on the lower substrate 1870.

A plurality of driving components are mounted on the printed circuit board 2000. Since the driving components are one-chip semiconductor chips 100, the driving components can collectively apply gate driving signals and data driving signals to the gate chip film package 1950 and the data chip film package 1900, respectively.

The gate lines 1875 are equidistantly arranged in an effective display region where a picture is displayed. The gate lines 1875 form groups of narrowly arranged gate lines in a non-display region corresponding to an edge of the lower substrate 1870 to be easily connected to the gate chip film packages 1950.

Likewise, the data lines 1895 are equidistantly arranged in an effective display region where a picture is displayed. The data lines 1895 may form groups of narrowly arranged data lines in the non-display region corresponding to the edge of the lower substrate 1870 to be easily connected to the data chip film packages 1900.

The gate chip film package 1950 includes wiring patterns formed on a base film, and gate driving semiconductor chips electrically connected to the wiring patterns. The gate driving semiconductor chips are mounted on the wiring patterns of the gate chip film package 1950 by a tape automated bonding (TAB) process. The gate chip film package 1950 transfers the gate driving signals output from a printed circuit board 2000 to the thin film transistors of the lower substrate 1870.

The data chip film packages 1900 can be divided into first data chip film packages for supplying both the gate driving signals and the data driving signals, and second data chip film packages for supplying data driving signals.

The first data chip film package includes wiring patterns formed on the base film and data driving semiconductor chips electrically connected to the wiring patterns. The data driving semiconductor chips may be mounted on the wiring patterns of the first data chip film package by a TAB process. Some of the wiring patterns are connected to first gate driving signal transmission lines of the lower substrate 1870 but not to the data driving semiconductor chips, thereby transmitting the gate driving signals output from the printed circuit board 2000 to the gate chip film packages 1950. The rest of the wiring patterns are connected to the data lines 1895 of the lower substrate 1870 and to the data driving semiconductor chips, thereby transmitting the data driving signals output from the printed circuit board 2000 to the thin film transistors of the lower substrate 1870.

Like the first data chip film package, the second data chip film package adjacent to the first data chip film package includes wiring patterns formed on the base film and data driving semiconductor chips electrically connected to the wiring patterns. The data driving semiconductor chips are mounted on the wiring patterns by a TAB process. The second data chip film package transfers the data driving signals output from the printed circuit board 2000 to the thin film transistors of the lower substrate 1870.

First gate driving signal transmission lines 2100a are arranged at edges of the lower substrate 1870 between the gate chip film package and the first data chip film package that are close to each other. First ends of the first gate driving signal transmission lines 2100a extend toward the data lines 1895, and second ends of the first gate driving signal transmission lines 2100a extend toward the gate lines 1875.

Other gate driving signal transmission lines separated from the first gate driving signals transmission lines 2100a, such as, for example, second and third gate driving signal transmission lines 2100b and 2100c, are further disposed between the respective groups of the gate lines 1875.

In the display panel assembly 1800, signals are supplied from the printed circuit board 2000 to the display panel 1850 in the following manner.

When a picture signal output from an external information processor (not shown), for example, a host computer, is input to the printed circuit board 2000, the printed circuit board 2000 generates gate driving signals or data driving signals corresponding to the input picture signal.

The data driving signals generated from the printed circuit board 2000 are input to the data driving semiconductor chips via the wiring patterns of the data chip film packages 1900 and then processed by the data driving semiconductor chips. Thereafter, the processed data driving signals are fed to the data lines 1895 of the lower substrate 1870 via the wiring patterns of the first and second data chip film packages.

The gate driving signals generated from the printed circuit board 2000 are input to first gate driving signal transmission lines of the lower substrate 1870 via the wiring patterns of the first data chip film packages.

The gate driving signals transmitted along the first gate driving signal transmission lines are input to the gate driving semiconductor chips via the wiring patterns of the gate chip film packages 1950 and then processed by the gate driving semiconductor chips. Thereafter, the processed gate driving signals are fed to the gate lines 1875 of the lower substrate 1870 via the wiring patterns of the gate chip film packages 1950.

Some of the gate driving signals input along the first gate driving signal transmission lines are not processed by the gate driving semiconductor chip but are transmitted to an adjacent gate chip film package 1950 via second gate driving signal transmission lines.

Through the above-described procedure, when a gate output signal is applied to the gate lines 1875 of the lower substrate 1870, all of the thin film transistors belonging to a row are turned on by the gate output signal, and the turned-on thin film transistors allow the voltage of the data driving semiconductor chip to be output to the pixel electrode. As a result, an electric field is created between the pixel electrode and the common electrode. The created electric field varies orientation of liquid crystal molecules between the upper substrate 1890 and the lower substrate 1870, thereby displaying picture information on an external display.

While the present inventive concept has been particularly shown and described with reference to exemplary embodiments thereof, it will be understood by those of ordinary skill in the art that various changes in form and details may be made therein without departing from the spirit and scope of the present inventive concept as defined by the following claims. It is therefore desired that the present embodiments be considered in all respects as illustrative and not restrictive, reference being made to the appended claims rather than the foregoing description to indicate the scope of the inventive concept.

What is claimed is:

1. A semiconductor package comprising:
a film including a hole;
a plating pattern formed under the film;
a semiconductor chip placed in the hole and electrically connected to the plating pattern; and
a first passivation layer formed on the semiconductor chip and the plating pattern.

2. The semiconductor package of claim 1, wherein the plating pattern comprises:
a first plating pattern electrically connected to a metal pad positioned under the semiconductor chip; and
a second plating pattern formed under the first plating layer.

3. The semiconductor package of claim 2, wherein a distance between two ends of the first plating pattern facing each other is smaller than a distance between two ends of the second plating pattern facing each other.

4. The semiconductor package of claim 3, further comprising a molding member covering the semiconductor chip and a portion of the film, wherein an end of the film penetrates into the molding member.

5. The semiconductor package of claim 4, further comprising:
a molding member covering the semiconductor chip;
a redistribution pattern layer formed on a bottom surface of the molding member and electrically connected to the plating layer; and
a coating material positioned on the film and contacting a side surface of the molding member.

6. The semiconductor package of claim 1, further comprising:
a molding member covering the semiconductor chip and a portion of the film;
a redistribution pattern layer formed on a bottom surface of the molding member and electrically connected to the plating layer; and
a coating material positioned on the film and contacting a side surface of the molding member,
wherein an end of the film penetrates into the molding member.

7. The semiconductor package of claim 1, further comprising:
a molding member covering the semiconductor chip;
a redistribution pattern layer formed on a bottom surface of the molding member and electrically connected to the plating layer through a connection member; and
a coating material positioned on the film and contacting a side surface of the molding member.

8. The semiconductor package of claim 7, wherein the connection member is a connection bump or an anisotropic conductive film (ACF).

9. The semiconductor package of claim 8, further comprising an adhesive material formed between the plating layer and the film.

10. The semiconductor package of claim 5, wherein the redistribution pattern layer is formed on the bottom surface of the molding member through a semiconductor device fabrication (FAB) process.

11. A display panel assembly comprising:
a display panel having a plurality of connection terminals along a periphery of the display panel; and
a semiconductor package on which semiconductor chips are mounted, wherein the semiconductor package is electrically connected to the connection terminals,
wherein the semiconductor package comprises:
a film including a hole;
a plating pattern formed under the film;
a semiconductor chip placed in the hole and electrically connected to the plating pattern; and
a first passivation layer formed on the semiconductor chip and the plating pattern.

12. The display panel assembly of claim 11, wherein the plating pattern comprises:
a first plating pattern electrically connected to a metal pad positioned under the semiconductor chip; and
a second plating pattern formed under the first plating layer.

13. The display panel assembly 12, wherein a distance between two ends of the first plating pattern facing each other is smaller than a distance between two ends of the second plating pattern facing each other.

14. The display panel assembly of claim 13, further comprising:
a metal pad formed under the semiconductor chip and electrically connecting the plating layer and the semiconductor chip to each other; and
a molding member covering the semiconductor chip and a portion of the film,
wherein an end of the film penetrates into the molding member.

15. The display panel assembly of claim 11, further comprising:
a molding member covering the semiconductor chip;
a redistribution pattern layer formed on a bottom surface of the molding member and electrically connected to the plating layer; and
a coating material positioned on the film and contacting a side surface of the molding member.

16. The display panel assembly of claim 11, further comprising:
a molding member covering the semiconductor chip and a portion of the film;
a redistribution pattern layer formed on a bottom surface of the molding member and electrically connected to the plating layer; and
a coating material positioned on the film and contacting a side surface of the molding member,
wherein an end of the film penetrates into the molding member.

17. The display panel assembly of claim 11, further comprising:
a molding member covering the semiconductor chip;
a redistribution pattern layer formed on a bottom surface of the molding member and electrically connected to the plating layer through a connection member; and
a coating material positioned on the film and contacting a side surface of the molding member.

18. A semiconductor package comprising:
a plating layer;
a semiconductor chip on the plating layer, wherein the semiconductor chip is electrically connected to the plating layer via a metal pad; and
a film on the plating layer, wherein the film surrounds the semiconductor chip.

19. The semiconductor package of claim 18, wherein the plating pattern comprises:
a first plating pattern; and
a second plating pattern under the first plating layer.

20. The semiconductor package of claim 19, wherein a distance between two ends of the first plating pattern facing each other is smaller than a distance between two ends of the second plating pattern facing each other.
